(19) United States
(12) Patent Application Publication
(10) Pub. No.: US 2008/0093663 A1
(43) Pub. Date: Apr. 24, 2008

(54) Nonvolatile memory device and method for forming the same

(76) Inventors: Jang-hee Lee, Yongin-si (KR); Gil-Heyun Choi, Seoul (KR); Byung-hee Kim, Seoul (KR); Tae-Ho Cha, Seongnam-si (KR); Hee-Sook Park, Seoul (KR); Geum-Jung Seong, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/882,654

(22) Filed: Aug. 3, 2007

(30) Foreign Application Priority Data
Oct. 20, 2006 (KR) 2006-102374

(51) Int. Cl. H01L 21/336; H01L 29/792

(52) U.S. Cl. 257/324; 438/260; 257/E29.309; 257/E21.409

(57) ABSTRACT

A method of forming a memory device includes forming a first insulating pattern and a polysilicon pattern in a peripheral region of a substrate, forming a cell gate insulating pattern including a second insulating pattern, a charge storage pattern, and a third insulating pattern in a cell region of the substrate, forming a barrier metal layer on the polysilicon pattern and on the third insulating pattern, forming a conductive layer on the barrier metal layer, patterning the conductive layer to simultaneously form a first conductive pattern on the polysilicon pattern and a second conductive pattern on the third insulating pattern, and patterning the barrier metal layer to simultaneously form a first barrier metal pattern on the polysilicon pattern and a second barrier metal pattern on the third insulating pattern.

### BACKGROUND OF THE INVENTION

1. Field of the Invention

The present invention relates to a semiconductor device and a method of forming the same. More particularly, the present invention relates to a memory device and a method for forming the same.

2. Description of the Related Art

Semiconductor memory devices generally include volatile memory devices, which lose stored information when a power supply is cut off, and nonvolatile memory devices, which retain stored information even when not powered. Nonvolatile memory devices include, e.g., a flash memory device, which may be a floating gate type or a charge trap type, according to the kind of data storage layer used for the unit cell.

Generally, the floating gate type flash memory device stores charges in a polysilicon layer, whereas the charge trap type flash memory device stores charges in a trap site formed in a nonconductive charge trap layer. A SONOS (silicon-oxide-nitride-oxide-silicon) memory cell is a charge trap type memory device, and may include a stacked structure in which a tunnel oxide layer, a silicon nitride layer (charge trap layer), a blocking oxide layer, and a gate formed of polysilicon are sequentially stacked on a silicon substrate.

As the degree of integration of semiconductor memory devices increases, a gate electrode has a smaller line width, which may cause an unwanted increase in electric resistance and negatively affect the resistor-capacitor (RC) delay. Such problems may become severe in the case of the SONOS memory device, which may have a gate electrode formed of high-resistivity polysilicon. Therefore, recently, a MONOS (metal-oxide-nitride-oxide-silicon) memory device including a metal gate electrode formed of a metal material has been proposed. However, despite the low resistivity thereof, the metal gate electrode may lower the reliability of a gate insulating layer if it directly contacts the gate insulating layer. For this reason, a polysilicon layer and a barrier metal layer may be disposed between a gate insulating layer and a metal layer constituting a gate electrode of a peripheral circuit in a peripheral region. However, since the barrier metal layer is formed in a cell region as well, the manufacturing process may become complicated, and an unnecessary layer may be added in the cell region.

### SUMMARY OF THE INVENTION

The present invention is therefore directed to a method of forming a memory device through a simplified manufacturing process, and a memory device formed by the method, which substantially overcome one or more of the problems due to the limitations and disadvantages of the related art.

It is therefore a feature of an embodiment of the present invention to provide a memory device in which a barrier metal layer having a high work function may be formed.

It is therefore another feature of an embodiment of the present invention to provide a memory device in which a cell gate electrode may be formed from a barrier metal layer, thereby simplifying the manufacturing process.

At least one of the above and other features and advantages of the present invention may be realized by providing a method of forming a memory device, including forming a first insulating pattern and a polysilicon pattern in a peripheral region of a substrate, forming a cell gate insulating pattern including a second insulating pattern, a charge storage pattern, and a third insulating pattern in a cell region of the substrate, forming a barrier metal layer on the polysilicon pattern and on the third insulating pattern, forming a conductive layer on the barrier metal layer, patterning the conductive layer to simultaneously form a first conductive pattern on the polysilicon pattern and a second conductive pattern on the third insulating pattern, and patterning the barrier metal layer to simultaneously form a first barrier metal pattern on the polysilicon pattern and a second barrier metal pattern on the third insulating pattern.

The barrier metal layer may be formed of a material having a work function of about 4.5 eV to about 5.0 eV. The barrier metal layer may be formed of metal nitride. The metal nitride may include one or more of tantalum nitride, titanium nitride, tungsten nitride, hafnium nitride, and zirconium nitride.

Forming the first insulating pattern and the polysilicon pattern may include forming a first insulating layer and a polysilicon layer on the semiconductor substrate, forming a mask pattern on the polysilicon layer, and patterning the polysilicon layer and the first insulating layer. The mask pattern may be formed of middle temperature oxide. Patterning the polysilicon layer may include removing the polysilicon layer in the cell region. The method may further include forming an ohmic layer on the polysilicon layer before the forming of the mask pattern. Patterning the polysilicon layer may further include patterning the ohmic layer to form an ohmic pattern, and the first barrier metal pattern, and the first conductive pattern may be formed on the ohmic pattern. Patterning the polysilicon layer may include removing the polysilicon layer and the ohmic layer in the cell region. Patterning the first insulating layer may include forming the first insulating pattern in the peripheral region, and removing the first insulating layer in the cell region.

Forming the cell gate insulating pattern may include forming a second insulating layer, a charge storage layer and a third insulating layer in the peripheral region and in the cell region after forming the first insulating pattern and the polysilicon pattern, and removing the mask pattern, the second insulating layer, the charge storage layer, and the third insulating layer in the peripheral region to expose the polysilicon pattern.

The second insulating pattern may be formed of metal oxide. The second barrier metal pattern may be a cell gate electrode.

At least one of the above and other features and advantages of the present invention may also be realized by providing a memory device, including a first insulating pattern in a peripheral region of a substrate, a peripheral gate pattern including a polysilicon pattern on the first insulating pattern, a first barrier metal pattern on the polysilicon pattern, and a first conductive pattern on the first barrier metal pattern, a cell gate insulating pattern in a cell region of the substrate, the cell gate insulating pattern including a second insulating pattern, a charge storage pattern on the second insulating pattern, and a third insulating pattern on the charge storage pattern, and a cell gate pattern including a second barrier metal pattern on the cell gate insulating pattern, and a second conductive pattern on the second barrier metal pattern, wherein the first barrier metal pattern and the second barrier metal pattern are made of a same material, and the first conductive pattern and the second conductive pattern are made of a same material.

The first barrier metal pattern and the second barrier metal pattern may have a work function of about 4.5 eV to about 5.0 eV. The first barrier metal pattern and the second barrier metal pattern may include metal nitride. The metal nitride may include one or more of tantalum nitride, titanium nitride, tungsten nitride, hafnium nitride, and zirconium nitride.

The device may further include an ohmic pattern between the polysilicon pattern and the first barrier metal pattern. The second barrier metal pattern may be a cell gate electrode.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a cross-sectional view of a memory device according to an embodiment of the present invention;

FIG. 2 illustrates a cross-sectional view of a memory device according to a second embodiment of the present invention;

FIGS. 3 through 8 illustrate cross-sectional views of stages in a method of forming the memory device illustrated in FIG. 1;

FIGS. 9 through 14 illustrate cross-sectional views of stages in a method of forming the memory device illustrated in FIG. 2; and

FIGS. 15A and 15B illustrate graphs of a change in work function of TiN according to the content of nitrogen (N) and heat treatment.

### DETAILED DESCRIPTION OF THE INVENTION

Korean Patent Application No. 2006-102374, filed on Oct. 20, 2006, in the Korean Intellectual Property Office, and entitled: “Nonvolatile Memory Device and Method for Forming the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that although terms such as “first” and “second” are used herein to describe various elements, these elements are not to be limited by these terms. Rather, these terms are only used to distinguish one element from another element. In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

### Structure of a Memory Device

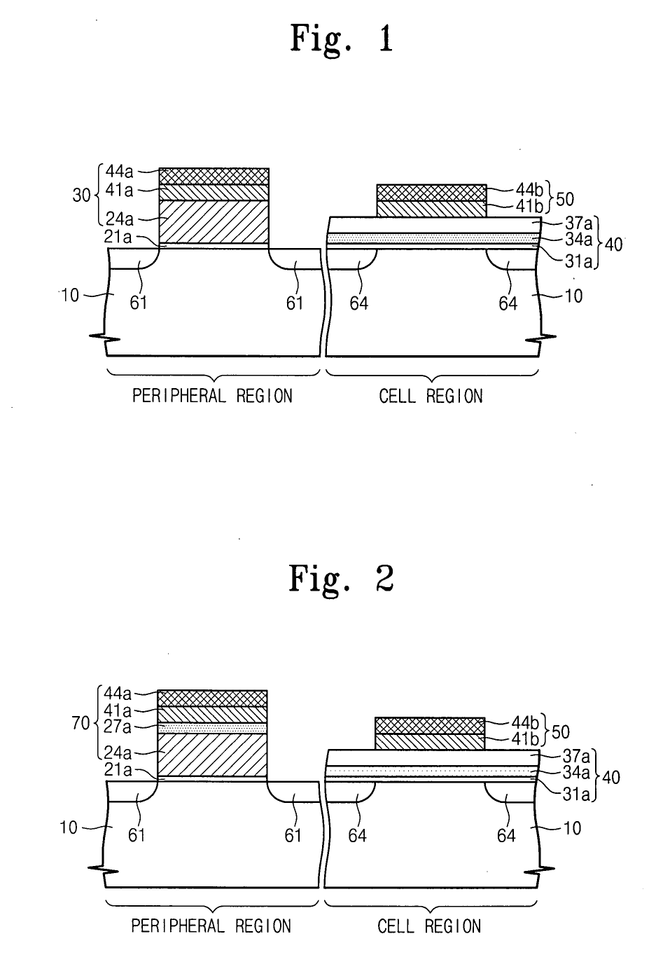

FIG. 1 illustrates a cross-sectional view of a memory device according to an embodiment of the present invention. The memory device may be, e.g., a non-volatile memory device. Referring to FIG. 1, a semiconductor substrate 10 may include a peripheral region and a cell region. The peripheral region may include, e.g., peripheral circuit transistors such as a high-voltage transistor and a low-voltage transistor. The cell region may include, e.g., memory cell transistors. A device isolation layer (not shown) may define active regions in the peripheral region and the cell region.

In the peripheral region, a first insulating pattern 21a may be on the substrate 10, and a peripheral gate pattern 30 may be on the first insulating pattern 21a. The peripheral gate pattern 30 may include, e.g., a polysilicon pattern 24a, a first barrier metal pattern 41a, and a first conductive pattern 44a. Impurity regions 61 may be formed in the substrate 10 at opposite sides of the peripheral gate pattern 30. The peripheral gate pattern 30 and the impurity regions 61 may form a peripheral circuit transistor, and the first insulating pattern 21a may be used as a gate insulating layer of the peripheral circuit transistor.

In the cell region, a cell gate insulating pattern 40 may be on the substrate 10, and a cell gate pattern 50 may be on the cell gate insulating pattern 40. The cell gate insulating pattern 40 may include, e.g., a second insulating pattern 31a, a charge storage pattern 34a, and a third insulating pattern 37a. The second insulating pattern 31a may be a tunneling insulating layer, and may include, e.g., silicon oxide. The charge storage pattern 34a may be a material layer for charge storage, and may include, e.g., one or more of silicon nitride and silicon oxide nitride. The charge storage pattern 34a may have an energy band structure that can trap and confine electrons or holes. The third insulating pattern 37a may be a blocking insulating layer having an energy band structure that can confine the trapped charges in the charge storage pattern 34a, and may include metal oxide, e.g., aluminum oxide. Also, the third insulating pattern 37a may include a material that can increase a coupling ratio so as to improve the performance of the memory device. The third insulating pattern 37a may be resistant to etching damage.

The cell gate pattern 50 may include a second barrier metal pattern 41b and a second conductive pattern 44b. Impurity regions 64 may be formed in the substrate 10 at opposite sides of the cell gate pattern 50. The cell gate insulating pattern 40, the cell gate pattern 50, and the impurity regions 64 may form a memory cell transistor. The cell gate insulating pattern 40 may be formed to correspond to the cell gate pattern 50, to correspond to an active region within the cell region, and/or to correspond to the cell region.

The first barrier metal pattern 41a in the peripheral region and the second barrier metal pattern 41b in the cell region may be formed of a same material, and the first conductive pattern 44a in the peripheral region and the second conductive pattern 44b in the cell region may be formed of a same material. The first and second barrier metal patterns 41a and 41b may include, e.g., a material having a work function of about 4.5 eV to about 5.0 eV, such as a metal nitride. The metal nitride may include, e.g., one or more of tantalum nitride (TaN), titanium nitride (TiN), tungsten nitride (WN), hafnium nitride (HfN), and zirconium nitride (ZrN). The first and second conductive patterns 44a and 44b may include a metal material, e.g., tungsten.

The first and second barrier metal patterns 41a and 41b may prevent a material in the first and second conductive patterns 44a and 44b, which are formed respectively thereon, from being diffused downwards. Also, the second barrier metal pattern 41b in the cell region may serve as a gate electrode because of its high work function. Thus, the first and second barrier metal patterns 41a and 41b of the same material may perform different functions according to their locations.

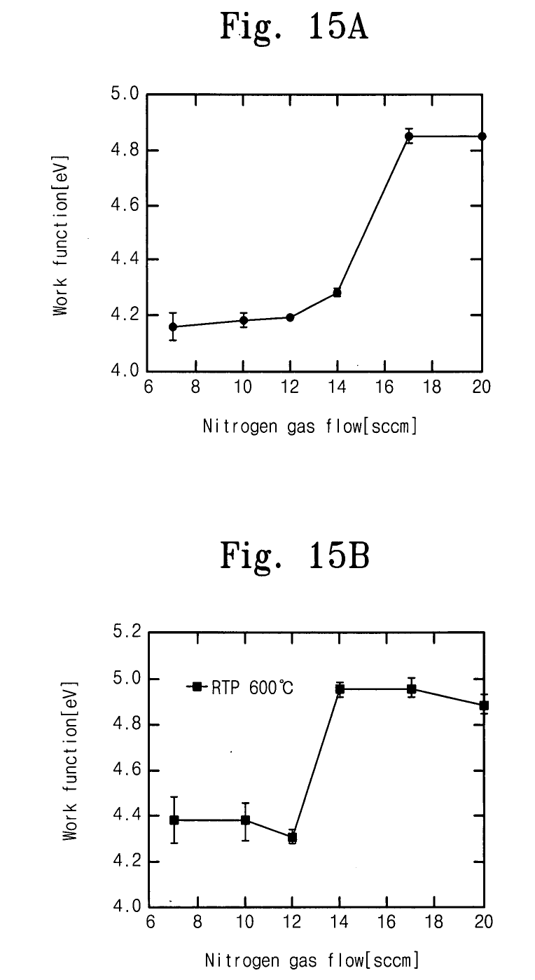

FIGS. 15A and 15B illustrate graphs of a change in work function of TiN according to the content of nitrogen (N) and heat treatment. In particular, FIG. 15A illustrates a graph showing a change in work function of TiN according to a content of nitrogen (N), and FIG. 15B illustrates a graph showing a change in work function of TiN according to heat treatment. In FIGS. 15A and 15B, the horizontal axis represents nitrogen gas flow injected in a process chamber when TiN is deposited on a semiconductor substrate, and the vertical axis represents the work function of TiN.

Referring to FIG. 15A, it is apparent that, as the flow of nitrogen gas increases, the work function of TiN also increases. For example, TiN deposited with a nitrogen gas flow of about 15 sccm has a work function of about 4.5 eV, and TiN deposited with a nitrogen gas flow of about 17 sccm has a work function of about 4.9 eV.

Referring to FIG. 15B, it is apparent that the work function increases when rapid heat treatment is performed at about 600° C. after TiN is deposited. For example, TiN deposited with a nitrogen gas flow of about 13 sccm and then processed with rapid heat treatment at about 600° C. has a work function of about 4.6 eV, and TiN deposited with a nitrogen gas flow of about 14 sccm and then processed with rapid heat treatment at about 600° C. has a work function of about 5.0 eV. Accordingly, TiN with a desired work function may be obtained by properly controlling the nitrogen gas flow during deposition of TiN, and by performing a heat treatment after the deposition of TiN. Referring again to FIG. 1, in an implementation, the second barrier metal pattern 41b may be formed of a material having a work function of about 4.5 eV to about 5.0 eV. The second barrier metal pattern 41b may serve as a gate electrode.

FIG. 2 illustrates a cross-sectional view of a memory device according to a second embodiment of the present invention. In the following description of the second embodiment, those features that are different from the first embodiment will be mainly described. For clarity, a detailed description of features that are substantially the same in the second embodiment as those described in the first embodiment will not be repeated.

Referring to FIG. 2, an ohmic pattern 27a may be disposed between a polysilicon pattern 24a and a first barrier metal pattern 41a in a peripheral gate pattern 70 in the peripheral region of the substrate 10. The ohmic pattern 27a may include, e.g., a metal silicide such as one or more of tungsten silicide and titanium silicide. The ohmic pattern 27a may help reduce contact resistance between the polysilicon pattern 24a and the first barrier metal pattern 41a. Thus, signal delay in a peripheral circuit, which may be caused by an increased contact resistance, and defective operation of the memory device caused by the signal delay, may be reduced or eliminated.

### Method for Forming a Memory Device

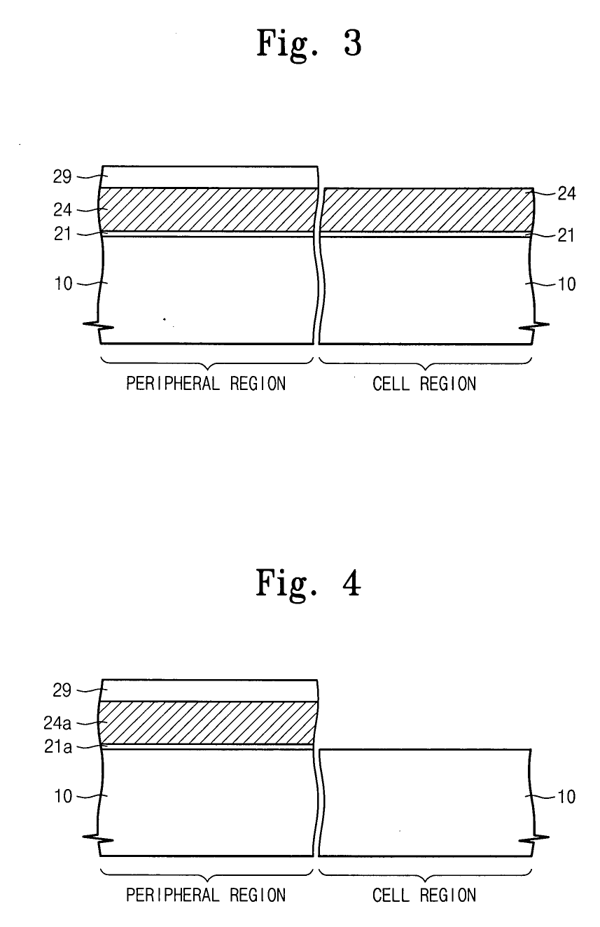

FIGS. 3 through 8 illustrate cross-sectional views of stages in a method of forming the memory device illustrated in FIG. 1. Referring to FIG. 3, a semiconductor substrate 10 may have a peripheral region and a cell region. A device isolation layer (not shown) defining active regions may be formed in the semiconductor substrate 10. The device isolation layer may be formed using, e.g., a general trench technology, a self-aligned trench technology, etc. A first insulating layer 21 may be formed on the substrate 10, and a polysilicon layer 24 may be formed on the first insulating layer 21. The first insulating layer 21 may be formed of, e.g., silicon oxide, and may be formed by, e.g., a thermal oxidation process, a chemical vapor deposition (CVD) process, etc.

The first insulating layer 21 may be used to form a gate insulating layer of peripheral circuit transistors formed in the peripheral region. The first insulating layer 21 may be formed to have a thickness that varies according to a location where the peripheral circuit transistors are formed. For example, the first insulating layer 21 may be relatively thick in a high-voltage region where a high-voltage transistor is formed, and may be relatively thin in a low-voltage region where a low-voltage transistor is formed. A mask pattern 29 may be formed on the polysilicon layer 24 in the peripheral region. The mask pattern 29 may be formed of, e.g., middle temperature oxide (MTO).

Referring to FIG. 4, an etching process may be performed using the mask pattern 29 as an etch mask to form a first insulating pattern 21a and a polysilicon pattern 24a in the peripheral region. The first insulating layer 21 and the polysilicon layer 24 in the cell region may be removed to expose the semiconductor substrate 10.

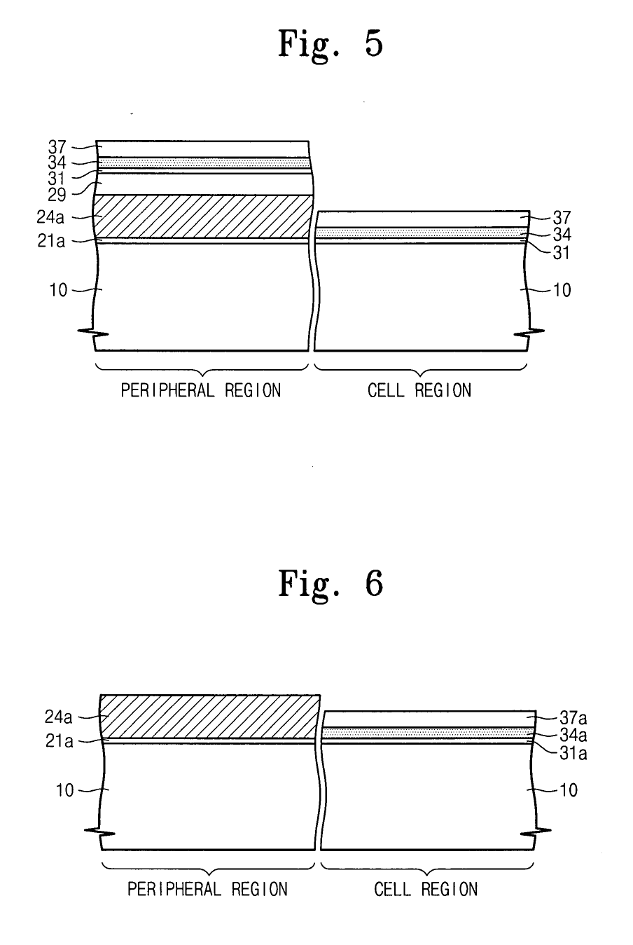

Referring to FIG. 5, a second insulating layer 31, a charge storage layer 34, and a third insulating layer 37 may be formed on the substrate 10. The second insulating layer 31 may be formed of, e.g., silicon oxide, and may be formed by, e.g., a thermal oxidation process, a CVD process, etc. The charge storage layer 34 may be formed of, e.g., one or more of silicon nitride and silicon oxide nitride, and may be formed by, e.g., a CVD process, an atomic layer deposition (ALD) process, etc. The third insulating layer 37 may be formed of, e.g., a metal oxide such as aluminum oxide.

Referring to FIG. 6, the second insulating layer 31, the charge storage layer 34, and the third insulating layer 37 may be patterned to form a second insulating pattern 31a, a charge storage pattern 34a, and a third insulating pattern 37a in the cell region. The mask pattern 29, the second insulating layer 31, the charge storage layer 34, and the third insulating layer 37 in the peripheral region may be removed to expose the polysilicon pattern 24a.

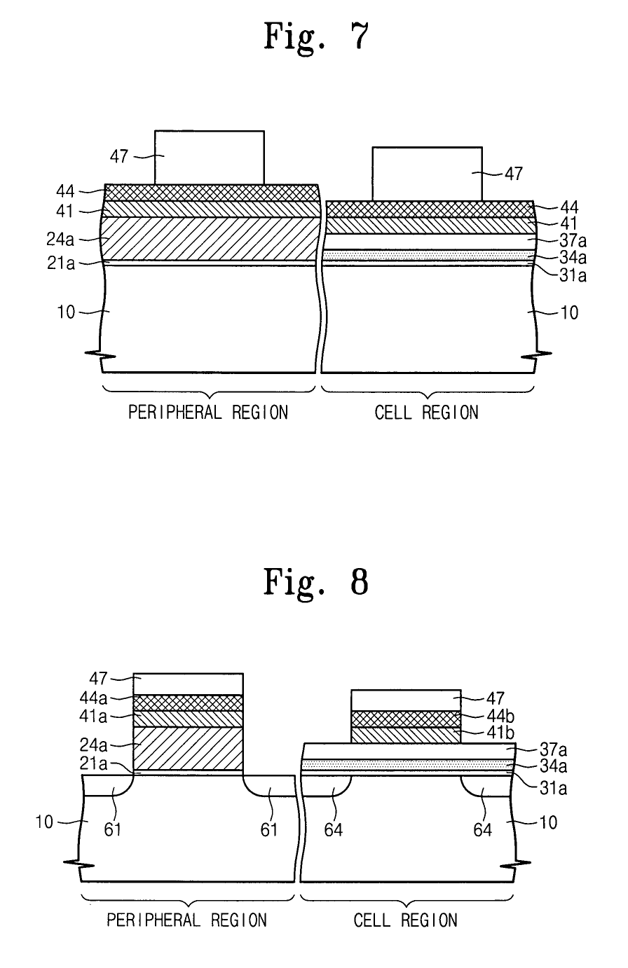

Referring to FIG. 7, a barrier metal layer 41 may be formed on the substrate on the polysilicon pattern 24a and on the third insulating pattern 37a. The barrier metal layer 44a may be formed of, e.g., metal nitride, and may have a work function of about 4.5 eV to about 5.0 eV. For example, the barrier metal layer 41 may be formed of one or more of TaN, TiN, WN, HfN, and ZrN, and may be formed by, e.g., a CVD process, a physical vapor deposition (PVD) process, an ALD process, etc. As described above, the barrier metal layer 41 having a desired work function may be formed by properly controlling the flow of nitrogen gas supplied to a process chamber in which a deposition process is performed, and by a heat treatment performed thereafter.

A conductive layer 44 may be formed on the barrier metal layer 41, and a mask pattern 47 may be formed on the conductive layer 44. The conductive layer 44 may be formed of, e.g., a metal material such as tungsten, and the mask pattern 47 may be formed of, e.g., a plasma enhanced oxide (PEOX).

Referring to FIG. 8, an etching process may be performed using the mask pattern 47 as an etch mask to pattern the barrier metal layer 41 and the conductive layer 44 to form a first barrier metal pattern 41a and a first conductive pattern 44a on the polysilicon pattern 24a in the peripheral region, and to form a second barrier metal pattern 41b and a second conductive pattern 44b on the third insulating pattern 37a in the cell region. As illustrated in FIG. 8, the mask pattern 47 may be etched while the barrier metal layer 41 and the conductive layer 44 are being etched in the etching process, and thus the thickness thereof may be decreased.

The polysilicon pattern 24a and the first insulating pattern 21a along sides of the mask pattern 47 in the peripheral region may be etched and removed by the etching process. However, in an implementation, the second insulating pattern 31a, the charge storage pattern 34a, and the third insulating pattern 37a along sides of the mask pattern 47 in the cell region may not be etched. It will be appreciated that whether the layers are etched or not may be suitably varied in other implementations (not shown).

Impurity regions 61 and 64 may be formed in the substrate 10, e.g., by an ion implantation process.

In this embodiment, the first barrier metal pattern 41a in the peripheral region and the second barrier metal pattern 41b in the cell region may be formed at the same time, and the first conductive pattern 44a in the peripheral region and the second conductive pattern 44b in the cell region may be formed at the same time. Thus, the manufacturing process of the memory device may be simplified.

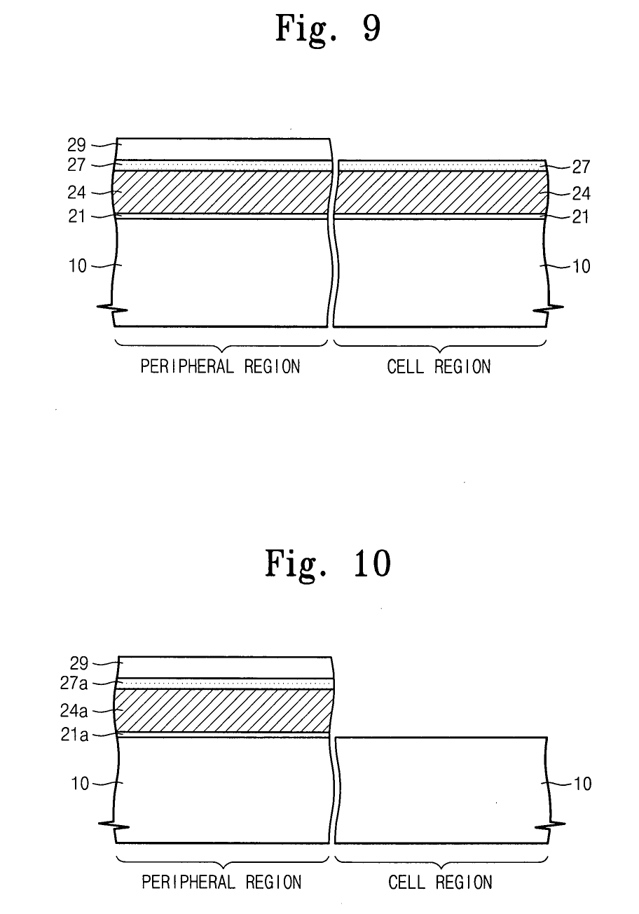

FIGS. 9 through 14 illustrate cross-sectional views of stages in a method of forming the memory device illustrated in FIG. 2. In the following description of the second embodiment, only those features that are different from the first embodiment will be mainly described. For clarity, a detailed description of features that are substantially the same in the second embodiment as those described in the first embodiment will not be repeated.

Referring to FIG. 9, a first insulating layer 21 may be formed on the substrate 10, a polysilicon layer 24 may be formed on the first insulating layer 21, and an ohmic layer 27 may be formed on the polysilicon layer 24. The first insulating layer 21 may be formed of, e.g., silicon oxide, and may be formed by, e.g., a thermal oxidation process, a CVD process, etc. The ohmic layer 27 may be formed of, e.g., metal silicide such as one or more of tungsten silicide and titanium silicide, and may be formed by, e.g., a CVD process, a PVD process, an ALD process, etc. A mask pattern 29 may be formed on the ohmic layer 27 in a peripheral region. The mask pattern 29 may be formed of, e.g., MTO.

Referring to FIG. 10, an etching process may be performed using the mask pattern 29 as an etch mask to form a first insulating pattern 21a, a polysilicon pattern 24a, and an ohmic pattern 27a in the peripheral region. Here, the first insulating layer 21, the polysilicon layer 24, and the ohmic layer 27 in the cell region may be removed to expose the semiconductor substrate 10.

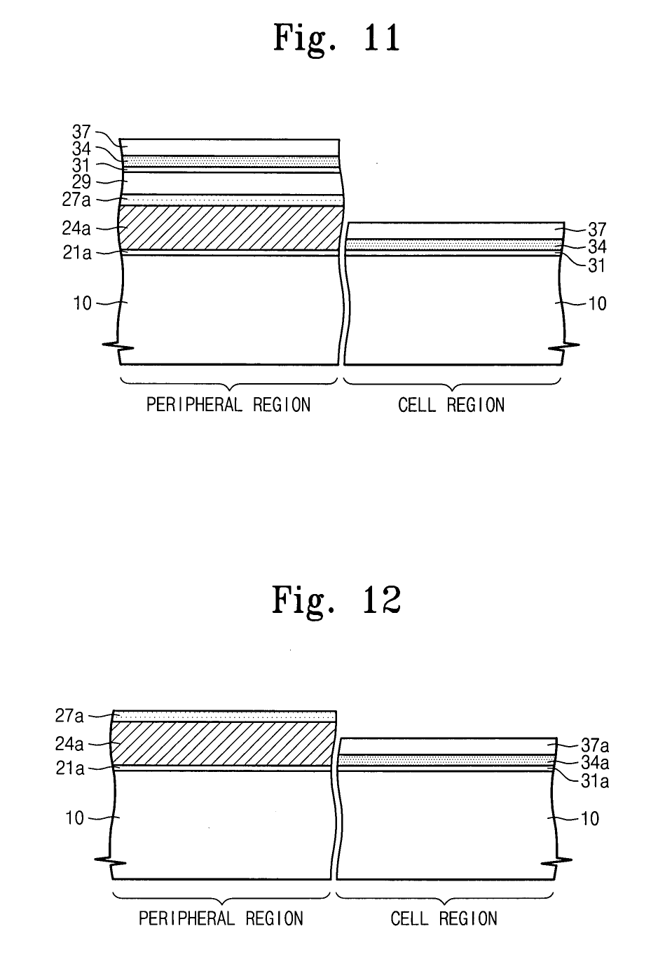

Referring to FIG. 11, a second insulating layer 31, a charge storage layer 34, and a third insulating layer 37 may be formed on the substrate 10. The second insulating layer 31 may be formed of, e.g., silicon oxide, and may be formed by, e.g., a thermal oxidation process, a CVD process, etc. The charge storage layer 34 may be formed of, e.g., one or more of silicon nitride and silicon oxide nitride, and may be formed by, e.g., a CVD process, an ALD process, etc. The third insulating layer 37 may be formed of, e.g., metal oxide such as aluminum oxide.

Referring to FIG. 12, the second insulating layer 31, the charge storage layer 34, and the third insulating layer 37 may be patterned to form a second insulating pattern 31a, a charge storage pattern 34a, and a third insulating pattern 37a on the cell region. The mask pattern 29, the second insulating layer 31, the charge storage layer 34 and the third insulating layer 37 in the peripheral region may be removed to expose the ohmic pattern 27a.

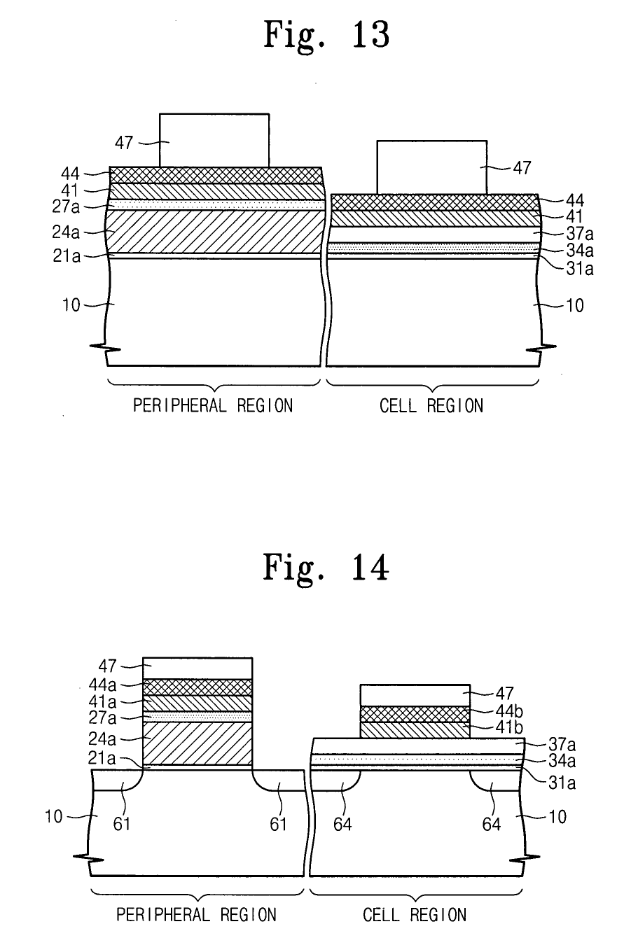

Referring to FIG. 13, a barrier metal layer 41 may be formed on the ohmic pattern 27a and on the third insulating pattern 37a. The barrier metal layer 41 may be formed of, e.g., metal nitride, and may have a work function of about 4.5 eV to about 5.0 eV. The barrier metal layer 41 may be formed of, e.g., one or more of TaN, TiN, WN, HfN and ZrN, and may be formed by, e.g., a CVD process, a PVD process, an ALD process, etc.

A conductive layer 44 may be formed on the barrier metal layer 41, and a mask pattern 47 may be formed on the conductive layer 44. The conductive layer 44 may be formed of a metal material, e.g., tungsten, and the mask pattern 47 may be formed of, e.g., PEOX.

Referring to FIG. 14, an etching process may be performed using the mask pattern 47 as an etch mask to pattern the barrier metal layer 41 and the conductive layer 44 so as to form a first barrier metal pattern 41a and a first conductive pattern 44a on the ohmic pattern 27a in the peripheral region, and to form a second barrier metal pattern 41b and a second conductive pattern 44b on the third insulating pattern 37a in the cell region. As illustrated in FIG. 14, the thickness of the mask pattern 47 may be reduced as it is etched while the barrier metal layer 41 and the conductive layer 44 are being etched in the etching process. During the etching process, the polysilicon pattern 24a and the first insulating pattern 21a at both sides of the mask pattern 47 in the peripheral region may be etched and removed. Thereafter, an ion implantation process may be performed to form impurity regions 61 and 64 in the substrate 10.

As in the first embodiment, in the second embodiment, the first barrier metal pattern 41a in the peripheral region and the second barrier metal pattern 41b in the cell region may be formed at the same time. Similarly, the first conductive pattern 44a in the peripheral region and the second conductive pattern 44b in the cell region may be formed at the same time. Thus, the manufacturing process of the memory device may be simplified.

According to embodiments of the present invention, a barrier metal layer having a high work function may be formed, and, since a cell gate electrode may be formed from the barrier metal layer, the manufacturing process may be simplified.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a memory device, comprising:
forming a first insulating pattern and a polysilicon pattern in a peripheral region of a substrate;
forming a cell gate insulating pattern including a second insulating pattern, a charge storage pattern, and a third insulating pattern in a cell region of the substrate;
forming a barrier metal layer on the polysilicon pattern and on the third insulating pattern;
forming a conductive layer on the barrier metal layer;
patterning the conductive layer to simultaneously form a first conductive pattern on the polysilicon pattern and a second conductive pattern on the third insulating pattern; and
patterning the barrier metal layer to simultaneously form a first barrier metal pattern on the polysilicon pattern and a second barrier metal pattern on the third insulating pattern.

2. The method as claimed in claim 1, wherein the barrier metal layer is formed of a material having a work function of about 4.5 eV to about 5.0 eV.

3. The method as claimed in claim 1, wherein the barrier metal layer is formed of metal nitride.

4. The method as claimed in claim 3, wherein the metal nitride comprises one or more of tantalum nitride, titanium nitride, tungsten nitride, hafnium nitride, and zirconium nitride.

5. The method as claimed in claim 1, wherein forming the first insulating pattern and the polysilicon pattern comprises:
forming a first insulating layer and a polysilicon layer on the semiconductor substrate;
forming a mask pattern on the polysilicon layer; and
patterning the polysilicon layer and the first insulating layer.

6. The method as claimed in claim 5, wherein the mask pattern is formed of middle temperature oxide.

7. The method as claimed in claim 5, wherein patterning the polysilicon layer comprises removing the polysilicon layer in the cell region.

8. The method as claimed in claim 5, further comprising forming an ohmic layer on the polysilicon layer before the forming of the mask pattern.

9. The method as claimed in claim 8, wherein patterning the polysilicon layer further comprises patterning the ohmic layer to form an ohmic pattern, and
the first barrier metal pattern and the first conductive pattern are formed on the ohmic pattern.

10. The method as claimed in claim 8, wherein patterning the polysilicon layer comprises removing the polysilicon layer and the ohmic layer in the cell region.

11. The method as claimed in claim 5, wherein patterning the first insulating layer comprises forming the first insulating pattern in the peripheral region, and removing the first insulating layer in the cell region.

12. The method as claimed in claim 11, wherein forming the cell gate insulating pattern comprises:
forming a second insulating layer, a charge storage layer and a third insulating layer in the peripheral region and in the cell region after forming the first insulating pattern and the polysilicon pattern; and
removing the mask pattern, the second insulating layer, the charge storage layer, and the third insulating layer in the peripheral region to expose the polysilicon pattern.

13. The method as claimed in claim 1, wherein the second insulating pattern is formed of metal oxide.

14. The method as claimed in claim 1, wherein the second barrier metal pattern is a cell gate electrode.

15. A memory device, comprising:
a first insulating pattern in a peripheral region of a substrate;
a peripheral gate pattern including a polysilicon pattern on the first insulating pattern, a first barrier metal pattern on the polysilicon pattern, and a first conductive pattern on the first barrier metal pattern;
a cell gate insulating pattern in a cell region of the substrate, the cell gate insulating pattern including a second insulating pattern, a charge storage pattern on the second insulating pattern, and a third insulating pattern on the charge storage pattern; and
a cell gate pattern including a second barrier metal pattern on the cell gate insulating pattern, and a second conductive pattern on the second barrier metal pattern, wherein:
the first barrier metal pattern and the second barrier metal pattern are made of a same material, and
the first conductive pattern and the second conductive pattern are made of a same material.

16. The device as claimed in claim 15, wherein the first barrier metal pattern and the second barrier metal pattern have a work function of about 4.5 eV to about 5.0 eV.

17. The device as claimed in claim 15, wherein the first barrier metal pattern and the second barrier metal pattern include metal nitride.

18. The device as claimed in claim 17, wherein the metal nitride comprises one or more of tantalum nitride, titanium nitride, tungsten nitride, hafnium nitride, and zirconium nitride.

19. The device as claimed in claim 15, further comprising an ohmic pattern between the polysilicon pattern and the first barrier metal pattern.

20. The device as claimed in claim 15, wherein the second barrier metal pattern is a cell gate electrode.
